(19) United States
(12) Patent Application Publication
(10) Pub. No.: US 2026/0159381 A1
(43) Pub. Date: Jun. 11, 2026

(54) METHOD FOR MANUFACTURING AN ELECTRONIC DEVICE

(71) Applicant: COMMISSARIAT À L'ENERGIE ATOMIQUE ET AUX ENERGIES ALTERNATIVES, Paris (FR)

(72) Inventors: Marie BOUSQUET, Grenoble (FR); Alexandre REINHARDT, Grenoble (FR); Pierre PERREAU, Grenoble (FR); Stéphane BALLERAND, Grenoble (FR); Joey DENIZART, Grenoble (FR)

(73) Assignee: COMMISSARIAT À L'ENERGIE ATOMIQUE ET AUX ENERGIES ALTERNATIVES, Paris (FR)

(21) Appl. No.: 19/409,213

(22) Filed: Dec. 4, 2025

(30) Foreign Application Priority Data
Dec. 6, 2024 (FR) 24/13578

(51) Int. Cl. B81C 1/00; B81B 7/00; H03H 3/007; H03H 3/02

(52) U.S. Cl. CPC B81C 1/00357; B81B 7/0025; H03H 3/0072; H03H 3/02; B81B 2201/0271; B81C 2201/0133; B81C 2201/0156; B81C 2201/019; B81C 2201/0192; B81C 2201/053; H03H 2003/027

(57) ABSTRACT

A method for manufacturing a resonant electronic device including a step of providing a primary stack including: a step of supplying an initial stack including an initial substrate having a front face including a central zone and a peripheral trimming zone, and a resonant thin layer made of piezoelectric material; and a protecting step, wherein a protective thin layer is deposited on the initial stack and covering the peripheral trimming zone; the protective thin layer being made of a material having an acoustic impedance greater than 20 MRayl for longitudinal waves and/or greater than 12 MRayl for shear waves. A resonant electronic device.

### TECHNICAL FIELD OF THE INVENTION

The present invention concerns the microelectronic devices comprising at least one resonant thin layer transferred onto a substrate.

More particularly, the invention concerns a method for forming a primary stack comprising a thin layer of a ferroelectric, pyroelectric, or piezoelectric material and a method for manufacturing an electronic device from such a primary stack.

### PRIOR ART

Various methods allowing to form a thin layer on a support substrate are known from the prior art. These may include, for example, physical deposition techniques such as molecular beam epitaxy (MBE), plasma sputtering, or pulsed laser deposition (PLD), or chemical deposition techniques such as sol-gel or metal organic chemical vapour deposition (MOCVD), or layer transfer techniques such as Smart Cut™ technology (crystal ion slicing), in which a thin layer is removed from a bulk substrate by fracturing at a fragile zone (or weakening plane) created in the bulk substrate by implanting light species (for example, H, He).

This latter method is particularly suited to forming a thin monocrystalline layer of piezoelectric material, which is used as a resonant system.

These resonant thin layers can be used, for example, in the manufacture of passive resonators or filters for surface acoustic waves (SAW), bulk acoustic waves (BAW), or lamb waves (also known as plate waves). These devices are particularly used in wireless communication systems, where they enable the segregation of the numerous signals picked up by the antennas of a communication terminal, thus ensuring the signal-to-noise ratio levels required by the existing telecommunication standards.

In these devices, the thickness of the resonant thin layer is a critical parameter for the proper functioning of the resonator or filter. Indeed, the width of the filter bandwidth is a function of the relative spacing between the resonance and antiresonance frequencies of the resonators that compose it. Yet, this difference is quantified by a so-called electromechanical coupling coefficient (k²), which also quantifies the fraction of energy that can be converted from the electrical domain to the mechanical domain, or vice versa, within a resonator at each oscillation period. This coefficient depends directly on the geometry of the resonator, the type of used wave, but also on the piezoelectric properties of the used material. The Smart Cut™ technology is therefore particularly suitable for the production of this type of device because it allows fine control of the thickness of the resonant thin layer. This technology also makes it possible to obtain thin layers with different orientations (for example, X-, Y-, Y+36°-, Y+163°-, or Z-cut), in different sizes (from 75 to 300 mm). Document US20220166398A1 describes a method for manufacturing such devices.

During the formation of substrates including this resonant thin layer, an edge-trimming step is performed at the wafer periphery, forming (for the disc-shaped substrates) a peripheral ring devoid of a resonant thin layer. This peripheral ring is particularly useful for the substrate transfer operations, as it allows their peripheral gripping by manufacturing equipment.

Nonetheless, in the manufacture of certain devices and in particular resonators and filters, such a peripheral ring also serves as an entry point for wafer edge infiltration. This damages the wafer containing the devices from the edges. Such infiltration generally occurs during transfer and etching steps, and particularly during chemical etching steps (for example, hydrofluoric acid etching). This is particularly damaging in the manufacture of resonators and filters, as hydrofluoric acid etching is often used for its selectivity towards the piezoelectric material. This results in substantial degradation of the devices at the edge of the wafer, which limits the production yields and increases the quantity of scrap.

Moreover, since the piezoelectric resonant thin layer is a sensitive layer in these devices, any layer that comes into contact with it can impair the performance of the devices. There is therefore a need to find a way to prevent degradation at the wafer edge during the formation of a stack comprising a piezoelectric resonant thin layer, without impairing the performance of said resonant thin layer.

### PURPOSE OF THE INVENTION

The purpose of the present invention is to propose a solution that addresses all or some of the aforementioned problems.

This aim can be achieved by implementing a method for forming a primary stack for manufacturing an electronic device, the forming method comprising:
a supply step, in which an initial stack is supplied, said initial stack comprising:
an initial substrate having a front face, said front face comprising a central zone and a peripheral trimming zone, the peripheral trimming zone being adjacent to a peripheral edge of the front face on the one hand, and surrounding the central zone on the other hand;
a resonant thin layer of piezoelectric material having an upper surface facing the initial substrate and a lower surface opposite the upper surface; and
a bonding layer, interposed between the central zone of the initial substrate, and the upper surface of the resonant thin layer;
a protecting step, in which a protective thin layer is deposited on the initial stack on the side of the lower surface of the resonant thin layer, said protective thin layer covering the peripheral trimming zone; the protective thin layer being made of a material having an acoustic impedance greater than 20 MRayl for longitudinal waves and/or greater than 12 MRayl for shear waves, the primary stack being formed at the end of the protecting step.

The provisions described above make it possible to propose a method for forming a primary stack comprising a protective thin layer intended to protect the resonant thin layer during subsequent steps of the method, in particular at the periphery of the protective thin layer.

Throughout the text and in general, 1 MRayl=106 kg/(m²·s).

The formation method may further have one or more of the following characteristics, taken alone or in combination.

According to one embodiment, during the protecting step, the protective thin layer is deposited so as to partially or completely cover the upper surface of the resonant thin layer, as well as the peripheral trimming zone.

Thus, it is possible to protect the resonant thin layer in a single step of the method. Moreover, depositing the protective thin layer over the entire visible surface of the initial stack allows simplifying the formation method, thereby reducing costs.

According to one embodiment, during the protecting step, the material of the protective thin layer is selected from the group consisting of AlN, Al₂O₃, HfN, HfO₂, SiₓN_{y}, Ta₂O₅, TiN, TaN, TiO₂, WO₃, ZnO, and ZrO₂.

Thus, the material selected for the protective thin layer is particularly suitable for protecting the resonant thin layer during a chemical etching step, particularly with hydrofluoric acid.

According to one embodiment, during the supply step, the resonant thin layer has a thickness of less than 2 μm, and particularly less than 1 μm.

In this way, the primary stack is suitable for the manufacture of radiofrequency filters.

According to one embodiment, the supply step comprises:
supplying a donor substrate comprising a thick layer, the donor substrate having a main face on the thick layer side;
implanting light species into the thick layer to generate a weakening plane and thus define the resonant thin layer between the weakening plane and the main face of the donor substrate;
bringing the main face of the donor substrate into contact with the front face of the initial substrate;
detaching the resonant thin layer at the weakening plane, by applying a heat treatment.

The steps described above make it possible to remove a thin layer from a bulk substrate by fracture, using Smart Cut™ technology, which makes it possible to form the resonant thin layer. One embodiment of such steps is described in the document US20230353115A1.

According to one embodiment, during the protecting step, the protective thin layer is made of silicon nitride and has a thickness less than or equal to 100 nm.

In this way, it is possible to benefit from the protection against etching by the high acoustic impedance material, and to have a protective thin layer thickness that is sufficiently low to avoid degrading the resonator's performance, particularly in terms of resonance frequency, coupling coefficient, and quality factor.

According to one embodiment, during the protecting step, the protective thin layer is made of aluminum nitride and has a thickness less than or equal to 50 nm.

In this way, it is possible to benefit from the protection against etching by the high acoustic impedance material, and to have a protective thin layer thickness that is sufficiently low to avoid degrading the resonator's performance, particularly in terms of resonance frequency, coupling coefficient, and quality factor.

According to one embodiment, during the supply step, the initial stack comprises lower electrodes in electrical contact with the lower surface of the resonant thin layer. Thus, it is possible to reestablish electrical contact at the resonant thin layer.

Generally, the lower electrodes are in direct contact with the resonant thin layer.

The purpose of the invention can also be achieved by implementing a method for manufacturing a resonant electronic device, the manufacturing method comprising:
a provision step, in which a primary stack obtained by a formation method as described above, and a receiver stack are provided, the receiver stack having a receiving face;
a step of depositing bonding layer, in which a bonding layer is deposited on the lower surface side of the resonant thin layer;
a bonding step, in which the receiving face of the receiver stack and the bonding layer are brought into intimate contact, so as to secure the primary stack to the receiver stack;
a removal phase, in which the initial substrate and the bonding layer are removed mechanically and chemically; and
an electrode definition step, in which upper electrodes are deposited on the upper surface of the resonant thin layer, then defined by photolithography, etching and resin removal, so that the upper electrodes are in electrical contact with the resonant thin layer.

The previously described arrangements make it possible to manufacture a resonant electronic device in which the protective thin layer provides protection against wet etching, particularly hydrofluoric acid. This makes it possible to limit damage to the resonant thin layer near the peripheral edge, in particular by infiltration.

Surprisingly, it was found that the presence of a protective thin layer with high acoustic impedance made it possible to protect the resonant thin layer without compromising the resonant performance of this layer. This is particularly counterintuitive in the manufacture of a resonant electronic device, where the presence of a high acoustic impedance layer near the resonant thin layer should, a priori, impair its performance.

The manufacturing method may further have one or more of the following characteristics, taken alone or in combination.

According to one embodiment, the bonding layer deposition step comprises depositing and forming the bonding layer by deposition and then planarization of this bonding layer on the lower surface of the resonant thin layer.

According to one embodiment, the bonding layer comprises a metal oxide such as silicon oxide SiO₂, or a polymer.

According to one embodiment, during the provision step, the receiver stack comprises an acoustic insulating layer, said acoustic insulating layer supporting the receiving face of the receiver stack.

The manufacturing method is thus suitable for manufacturing a bulk acoustic wave resonator.

According to one embodiment, the acoustic insulating layer is a Bragg mirror.

The manufacturing method is thus suitable for manufacturing a bulk acoustic wave resonator on a reflector.

According to one embodiment, the etching phase comprises:
a first etching step, in which the initial substrate is removed by grinding and then by anisotropic chemical etching; and
a second etching step, in which the bonding layer is removed by chemical etching with hydrofluoric acid.

Advantageously, the initial substrate is removed first by grinding to remove a larger quantity of material, then by selective chemical etching with the material of the initial substrate. Moreover, the second etching step makes it possible to selectively remove the bonding layer, generally formed of silicon dioxide, without damaging the resonant thin layer.

The purpose of the invention can also be achieved by implementing a resonant electronic device obtained by a manufacturing method as described above, the resonant electronic device comprising the successive stack of at least:
a receiver stack;
a bonding layer;
a protective thin layer comprising an electrically insulating material;
lower electrodes in direct contact with the protective thin layer;
a resonant thin layer of piezoelectric material having an opposing upper surface and lower surface, the lower surface being in electrical contact with the lower electrodes;
upper electrodes in electrical contact with the upper surface of the resonant thin layer;

In this resonant electronic device, the protective thin layer has an acoustic impedance greater than 20 MRayl for longitudinal waves and/or greater than 12 MRayl for shear waves.

The previously described arrangements make it possible to provide a resonant electronic device with few defects near the peripheral edge.

### BRIEF DESCRIPTION OF THE DRAWINGS

Other aspects, aims, advantages, and characteristics of the invention will become more apparent upon reading the following detailed description of preferred embodiments thereof, given by way of non-limiting example, and with reference to the accompanying drawings, in which:

FIG. 1 is a schematic representation of a supply step according to a particular embodiment of the invention.

FIG. 2 is a schematic representation of the formation method and a bonding layer deposition step according to a particular embodiment of the invention.

FIG. 3 is a schematic representation of the formation method and a removal phase according to a particular embodiment of the invention.

FIG. 4 is a schematic representation of certain steps of the manufacturing method.

FIG. 5 is a schematic representation of the formation method and the manufacturing method according to a particular embodiment of the invention.

### DETAILED DESCRIPTION

In the figures and in the remainder of the description, the same references represent identical or similar elements. Furthermore, the various elements are not shown to scale so as to enhance clarity. Moreover, the various embodiments and variants are not mutually exclusive and may be combined with one another.

As can be seen in FIGS. 1 to 5, the invention concerns a manufacturing method P2 of a resonant electronic device 100 comprising the steps of a method P1 for forming a primary stack 30 for manufacturing an electronic device 100.

The formation method P1 firstly comprises a supply step E1, in which an initial stack 10 is supplied. This initial stack 10 comprises in particular: an initial substrate 11 having a front face denoted «Fav», a resonant thin layer 13 made of piezoelectric material, and a bonding layer 15, interposed between the initial substrate 11 and the resonant thin layer 13.

FIG. 1 illustrates an embodiment of this supply step E1, comprising a succession of sub-steps making it possible to result in the supply of the initial stack 10, known under the name SmartCut™. Briefly, this embodiment may firstly comprise the supply E01 of a donor substrate 1. This donor substrate 1 comprises a thick layer 3 (having a thickness generally greater than 10 μm), and optionally a primary bonding layer 2 arranged on the thick layer 3. The donor substrate 1 thus has a main face fp3 on the side of the thick layer 3, and in particular on the side of the primary bonding layer 2.

An implantation step E02 may then be implemented, in which light chemical species are implanted in the thick layer 3 to generate a weakening plane Pf3 therein, and thus to define the resonant thin layer 13 between the weakening plane Pf3 and the main face fp3 of the donor substrate 1. It is therefore clearly understood that this weakening plane Pf3 will subsequently delimit the resonant thin layer 13 with the main face fp3.

A contacting step E03 is then implemented by bringing the main face fp3 of the donor substrate 1 into contact with the front face Fav of the initial substrate 11. As previously, it may be advantageous for the front face Fav of the initial substrate 11 to be formed on a secondary bonding layer 4. A bonding is thus achieved between the main face fp3 and the front face Fav via the primary and secondary bonding layers 2, 4. These primary and secondary bonding layers 2, 4 thus form a single bonding layer 15.

Finally, a detachment step E04 can be implemented. During this step, the resonant thin layer 13 is formed by detaching a portion 6 of the thick layer 3 at the embrittlement plane Pf3, for example by applying a heat treatment. It is therefore clearly understood that the resonant thin layer 13 is the portion of the thick layer 3 that remains attached to the secondary bonding layer 4 following the detachment of the portion 6 from the thick layer 3.

Such a variant of the supply step E1 is advantageously implemented to form a monocrystalline resonant thin layer 13 with a thickness typically less than 1 μm. Thus, the formation method P1 is suitable for the manufacture of optical or acoustic devices. In particular, the forming method P1 is suitable for the manufacture of acoustic resonators or filters, such as surface acoustic wave (SAW) resonators, bulk acoustic wave (BAW) resonators, or lamb wave resonators.

Regardless of the selected implementation variant, the result is the formation of the initial stack 10, which comprises
the initial substrate 11, in which the front face Fav comprises a central zone Zc and a peripheral trimming zone Zdp, the peripheral trimming zone Zdp being adjacent to a peripheral edge Bp of the front face Fav on the one hand, and surrounding the central zone Zc on the other hand;
the resonant thin layer 13 having an upper surface s13sup facing the initial substrate 11 and a lower surface s13inf opposite the upper surface s13sup; and
the bonding layer 15, interposed between the central zone Zc of the initial substrate 11, and the upper surface s13sup of the resonant thin layer 13.

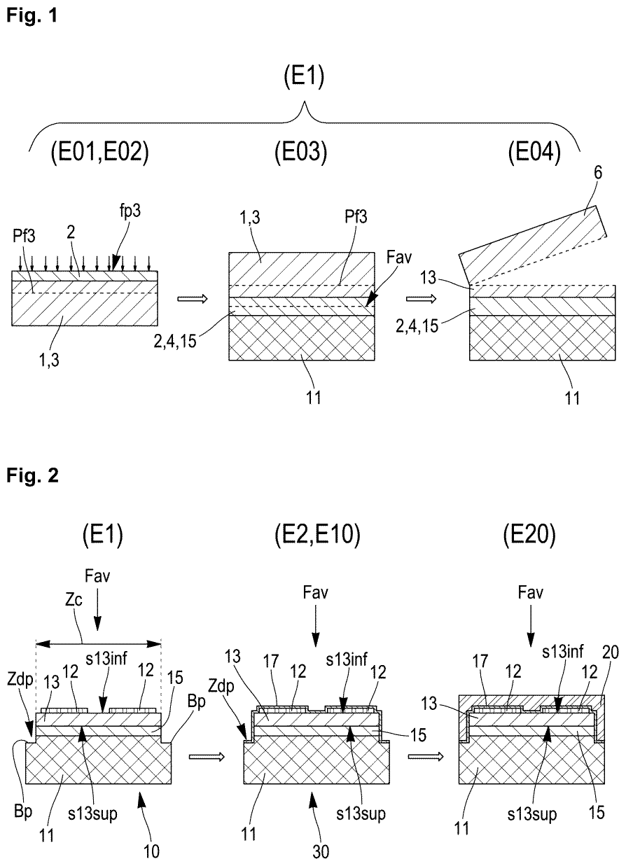

As illustrated in FIG. 2, in order to propose an initial stack 10 suitable for the fabrication of resonant electronic devices 100, the initial stack 10 may comprise lower electrodes 12 in electrical contact with the lower surface s13inf of the resonant thin layer 13. Generally, the lower electrodes 12 are in direct contact with the resonant thin layer 13. Thus, it is possible to reestablish electrical contact at the level of the resonant thin layer 13. Moreover, it is generally provided that the resonant thin layer 13 has a thickness of less than 2 μm, and in particular less than 1 μm. In this way, the primary stack 30 is suitable for manufacturing radiofrequency filters RF.

The formation method then comprises a protecting step E2, in which a protective thin layer 17 is deposited on the initial stack 10 on the lower surface s13inf of the resonant thin layer 13. This protective thin layer 17 covers the peripheral trimming zone Zdp and at least one portion of the upper surface.

As illustrated in FIG. 2, during the protecting step E2, the protective thin layer 17 is deposited so as to partially or completely cover the upper surface s13sup of the resonant thin layer 13, as well as the peripheral trimming zone Zdp. Thus, it is possible to protect the resonant thin layer 13 in a single method step. Moreover, depositing the protective thin layer 17 over the entire visible surface of the initial stack 10 makes it possible to simplify the formation method, which reduces costs.

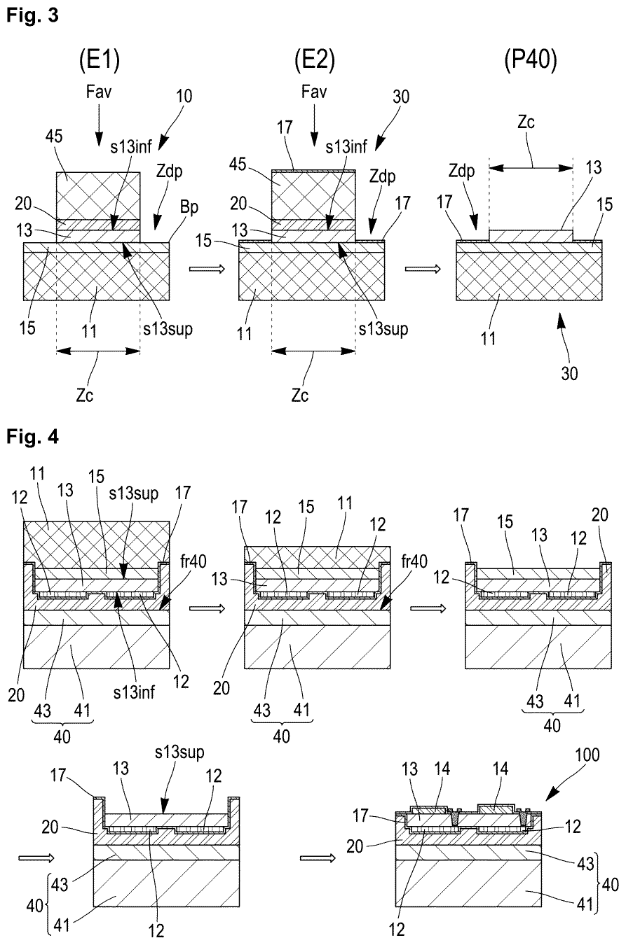

In the embodiment of FIG. 3, the protective thin layer 17 is deposited on the side of the front face Fav, and covers the peripheral trimming zone Zdp. It covers the temporary support 45 arranged on the front face Fav, as well as the lower surface s13inf and a bonding layer 20 interposed between the temporary support 45 and the lower surface s13inf. It is then possible to implement an etching phase P40 (which will be described later), to remove the temporary support 45 and the bonding layer 20, thus forming the primary stack 30.

The protective thin layer 17 is made of a material having an acoustic impedance greater than 20 MRayl for longitudinal waves and/or greater than 12 MRayl for shear waves. Throughout the text and in general, 1 MRayl=106 kg/m²·s. For example, the material of the protective thin layer 17 is selected from the group consisting of aluminum nitride AlN, aluminum oxide Al₂O₃, hafnium nitride HfN, hafnium dioxide HfO₂, silicon nitride SiₓN_{y}, tantalum pentoxide Ta₂O₅, titanium nitride TiN, tantalum nitride TaN, titanium dioxide TiO₂, tungsten trioxide WO₃, zinc oxide ZnO, and zirconium dioxide ZrO₂. Thus, the material selected for the protective thin layer 17 is particularly suitable for protecting the resonant thin layer 13 during a hydrofluoric acid etching step.

According to a first variant, the protective thin layer 17 may be made of silicon nitride SiₓN_{y}, and may have a thickness less than or equal to 100 nm. In this way, it is possible to benefit from the protection against etching by the high acoustic impedance material, and to have a protective thin layer 17 thickness that is sufficiently low so as not to degrade the performance of the resonator, particularly in terms of resonance frequency, coupling coefficient, and quality factor.

According to a second variant, the protective thin layer 17 may be made of aluminum nitride AlN, and may have a thickness less than or equal to 50 nm. In this way, it is possible to benefit from the protection against etching by the high acoustic impedance material, and to have a protective thin layer 17 thickness that is sufficiently low so as not to degrade the performance of the resonator, particularly in terms of resonance frequency, coupling coefficient, and quality factor.

This formation method P1 results in the formation of a primary stack 30, obtained at the end of the protecting step E2.

All of the provisions described above make it possible to propose a method for forming a primary stack 30 comprising a protective thin layer 17 intended to protect the resonant thin layer 13 during subsequent steps of the method, in particular at the periphery of the protective thin layer 17.

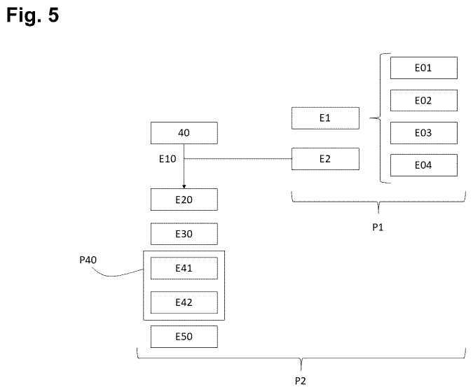

The manufacturing method P2 of a resonant electronic device 100, which is the subject of the invention, is illustrated in FIG. 5.

The manufacturing method P2 firstly comprises a provision step E10, in which a primary stack 30 obtained by the formation method P1, and a receiver stack 40 are provided. It is therefore possible for the steps of the formation method P1 as described above to be included in the manufacturing method P2. The receiver stack 40 has a receiving face fr40.

During the provision step E10, the receiver stack 40 generally comprises an acoustic insulating layer 43, said acoustic insulating layer 43 carrying the receiving face fr40 of the receiver stack 40. The manufacturing method P2 is thus suitable for the manufacturing of a bulk acoustic wave resonator. More precisely, this acoustic insulating layer 43 can be a Bragg mirror. The manufacturing method P2 is thus suitable for the manufacturing of a bulk acoustic wave resonator on a reflector.

As illustrated in FIG. 3, a bonding layer deposition step E20 is implemented, in which a bonding layer 20 is deposited on the lower surface side s13inf of the resonant thin layer 13. For example, this bonding layer 20 may comprise a metal oxide such as silicon oxide SiO₂, or a polymer.

Then, and as illustrated in FIG. 3, a bonding step E30 is implemented, in which the receiving face fr40 of the receiver stack 40, and the bonding layer 20 are brought into intimate contact, so as to secure the primary stack 30 with the receiver stack 40. As can be seen in the figure, during this bonding step E30, the primary stack 30 is returned towards the receiver stack 40, with the bonding layer 20 arranged between the two stacks 30, 40. This results in particular in an inversion of the position of the lower surfaces s13inf and upper surfaces s13sup of the resonant thin layer 13 in the figures.

The manufacturing method P2 then comprises a removal phase P40, one embodiment of which is illustrated in FIG. 4. During this removal phase P40, the initial substrate 11 and the bonding layer 15 are removed mechanically and chemically.

For example, the etching phase P40 may comprise:
a first etching step E41, in which the initial substrate 11 is removed by grinding and then by anisotropic chemical etching; and
a second etching step E42, in which the bonding layer 15 is removed by chemical etching with hydrofluoric acid.

Advantageously, the removal of the initial substrate 11 is carried out first by grinding to remove a larger quantity of material, then by selective chemical etching with the material of the initial substrate 11. Moreover, the second etching step E42 makes it possible to selectively remove the bonding layer 15, generally formed of silicon dioxide, without damaging the resonant thin layer 13.

Finally, an electrode definition step E50 is implemented, in which upper electrodes 14 are deposited on the upper surface s13sup of the resonant thin layer 13, then defined by photolithography, etching and resin removal, so that the upper electrodes 14 are in electrical contact with the resonant thin layer 13.

All of the arrangements described above make it possible to manufacture a resonant electronic device 100 in which the protective thin layer 17 provides protection against etching and in particular the hydrofluoric acid generally used during the etching phase P40. It is thus possible to limit damage to the resonant thin layer 13 near the peripheral edge Bp, in particular by infiltration.

Surprisingly, it has been found that the presence of a protective thin layer 17 having a high acoustic impedance makes it possible to protect the resonant thin layer 13 without compromising the resonance performance of this layer. This is particularly counterintuitive in the fabrication of a resonant electronic device 100, where the presence of a layer of high acoustic impedance near the resonant thin layer 13 should a priori impair its performance.

The invention also concerns a resonant electronic device 100 obtained by the fabrication method P2. This resonant electronic device 100 comprises the successive stack of at least:
a receiver stack 40;
a bonding layer 20;
a protective thin layer 17 comprising an electrically insulating material;
lower electrodes 12 in direct contact with the protective thin layer 17;
a resonant thin layer 13 made of piezoelectric material having an upper surface s13sup and a lower surface s13inf opposite each other, the lower surface s13inf being in electrical contact with the lower electrodes 12; and
upper electrodes 14 in electrical contact with the upper surface s13sup of the resonant thin layer 13;

In this resonant electronic device 100, the material of the protective thin layer 17 has an acoustic impedance greater than 20 MRayl for longitudinal waves and/or greater than 12 MRayl for shear waves. The arrangements described above make it possible to propose a resonant electronic device 100 having few defects near the peripheral edge Bp.

1. A manufacturing method of a resonant electronic device, the manufacturing method comprising the following successive steps:
a provision step, wherein a primary stack and a receiver stack are provided, the receiver stack having a receiving face; the primary stack being obtained by the following steps:
a supply step, wherein an initial stack is supplied, the initial stack comprising:
an initial substrate having a front face, the front face comprising a central zone and a peripheral trimming zone, the peripheral trimming zone being adjacent to a peripheral edge of the front face on the one hand, and surrounding the central zone on the other hand;
a thin resonant layer made of piezoelectric material having an upper surface facing the initial substrate and a lower surface opposite the upper surface;
a bonding layer, interposed between the central zone of the initial substrate, and the upper surface of the resonant thin layer; and
lower electrodes in electrical contact with the lower surface of the resonant thin layer
a protecting step, in wherein a protective thin layer is deposited on the initial stack on the side of the lower surface of the resonant thin layer, the protective thin layer covering the peripheral trimming zone; the protective thin layer being made of a material having an acoustic impedance greater than 20 MRayl for longitudinal waves and/or greater than 12 MRayl for shear waves, the primary stack being formed at the end of the protecting step;
a bonding layer deposition step, wherein a bonding layer is deposited on the lower surface side of the resonant thin layer;
a bonding step, wherein the receiving face of the receiver stack, and the bonding layer are brought into intimate contact, so as to secure the primary stack to the receiver stack;
a removal phase, wherein the initial substrate and the bonding layer are removed mechanically and chemically; and
an electrode definition step, wherein upper electrodes are deposited on the upper surface of the resonant thin layer, then defined by photolithography, etching and resin removal, so that the upper electrodes are in electrical contact with the resonant thin layer.

2. The manufacturing method according to claim 1, wherein during the protecting step, the protective thin layer is deposited so as to partially or completely cover the upper surface of the resonant thin layer, as well as the peripheral trimming zone.

3. The manufacturing method according to claims 1, wherein during the protecting step, the material of the protective thin layer is selected from the group consisting of AlN, Al₂O₃, HfN, HfO₂, SiₓN_{y}, Ta₂O₅, TiN, TaN, TiO₂, WO₃, ZnO, and ZrO₂.

4. The manufacturing method according to claim 1, wherein during the supply step, the resonant thin layer has a thickness of less than 2 μm.

5. The manufacturing method according to claim 1, wherein the supply step comprises:
supplying a donor substrate comprising a thick layer, the donor substrate having a main face on the side of the thick layer;
implanting light species in the thick layer to generate a weakening plane therein and thus define the resonant thin layer between the weakening plane and the main face of the donor substrate;
bringing the main face of the donor substrate into contact with the front face of the initial substrate;
detaching the resonant thin layer at the weakening plane, by applying a heat treatment.

6. The manufacturing method according to claims 1, wherein during the protecting step, the protective thin layer is made of silicon nitride, and has a thickness less than or equal to 100 nm.

7. The manufacturing method according to claims 1, wherein during the protecting step, the protective thin layer is made of aluminum nitride, and has a thickness less than or equal to 50 nm.

8. The manufacturing method according to claims 1, wherein during the provision step, the receiver stack comprises an acoustic insulating layer, the acoustic insulating layer supporting the receiving face of the receiver stack.

9. The manufacturing method according to claim 8, wherein the acoustic insulating layer is a Bragg mirror.

10. The manufacturing method according to claims 1, wherein the etching phase comprises:
a first etching step, wherein the initial substrate is removed by grinding and then by anisotropic chemical etching; and
a second etching step, wherein the bonding layer is removed by chemical etching with hydrofluoric acid.

11. A resonant electronic device obtained by a manufacturing method according to claim 1, the resonant electronic device comprising the successive stack of at least:
a receiver stack;
a bonding layer;
a protective thin layer comprising an electrically insulating material;
lower electrodes in direct contact with the protective thin layer;
a resonant thin layer made of piezoelectric material having an opposing upper surface and a lower surface, the lower surface being in electrical contact with the lower electrodes;
upper electrodes in electrical contact with the upper surface of the resonant thin layer; resonant electronic device wherein the material of the protective thin layer has an acoustic impedance greater than 20 MRayl for longitudinal waves and/or greater than 12 MRayl for shear waves.
